(19) United States
(12) Patent Application Publication
(10) Pub. No.: US 2002/0086493 A1
(43) Pub. Date: Jul. 4, 2002

(54) Manufacturing method of semiconductor device having DRAM capacitors

(76) Inventors: Ryo Kubota, Tokyo (JP); Ken Inoue, Tokyo (JP)

Correspondence Address: SUGHRUE, MION, ZINN, MACPEAK & SEAS, 2100 Pennsylvania Avenue, N.W., Washington, DC, 20037, US

(21) Appl. No.: 09/817,233

(22) Filed: Mar. 27, 2001

(30) Foreign Application Priority Data
Mar. 30, 2000 (JP) 094325/2000

(51) Int. Cl. H01L 21/20; H01L 21/8242

(52) U.S. Cl. 438/396; 438/239; 438/253; 438/395

(57) ABSTRACT

A manufacturing method of a semiconductor device having a CMOS logic circuit portion and a DRAM portion mixedly mounted on one chip. Preferably, the DRAM portion has a cylinder structure capacitor element. In the manufacturing method, the polysilicon film is formed on an interlayer film and on an inner wall of a cylinder-shaped opening formed in the interlayer film. Spherical or hemispherical grains called HSG are formed on the polysilicon film. The polysilicon film and the HSG on an upper surface of the interlayer film are removed while the polysilicon film and the HSG on the inner wall of the cylinder is retained. By performing these steps in this order, the HSG is reliably formed on the inner wall of the cylinder without fail. Therefore, a miniaturized capacitor element having high capacitance may be formed in a semiconductor device with a CMOS logic circuit portion and a DRAM portion mixedly mounted on one chip.

### BACKGROUND OF THE INVENTION

1. Field of the Invention

The present invention relates to a method of manufacturing a semiconductor device having a CMOS logic circuit portion and a DRAM mixedly mounted on one chip.

2. Description of the Related Art

In a general-purpose DRAM, a plurality of memory cells and peripheral circuits are formed on the same semiconductor substrate. The plurality of memory cells store information. The peripheral circuits comprise a decoding circuit and the like for selecting a memory cell.

A memory cell is provided with a capacitor element for storing information by accumulating signal charge, and with a transistor as a switching element for accumulating signal charge in the capacitor element and for reading signal charge accumulated in the capacitor element. It is to be noted that, as the transistor, an FET (Field Effect Transistor) of MOS (Metal Oxide Semiconductor) structure or of MIS (Metal Insulator Semiconductor) structure is used since they are advantageous in making the level of integration higher. As a transistor for the peripheral circuit, an FET having the same structure as that of the memory cell is used, for the purpose of unifying its manufacturing process to that of the memory cell.

These days, memory cells of general-purpose DRAMs are required to be miniaturized more and more for the purpose of increasing the level of integration of the general-purpose DRAM. However, since the capacitance value of a capacitor element basically depends on the area of electrodes and the relative dielectric constant of an insulating film sandwiched therebetween, special measures are required to accomplish both higher capacitance and miniaturization. Therefore, forming a capacitor element in a three-dimensional structure has been considered to secure predetermined capacitance. For example, a cylinder structure shown in FIG. 1 and a stack structure shown in FIG. 2 have been adopted.

FIG. 1 is a sectional side elevation showing the structure of a part of a general-purpose DRAM having capacitor elements of the cylinder structure, and FIG. 2 is a sectional side elevation showing the structure of a part of a general-purpose DRAM having capacitor elements of the stack structure.

As shown in FIG. 1, in the capacitor element of the cylinder structure, a groove (cylinder 103) is formed in an interlayer film 102 formed on the whole surface of a substrate.

A lower electrode (hereinafter also referred to as a capacitor lower electrode) 104 is formed along on the inner wall of the cylinder 103. The lower electrode 104 is made of a polysilicon film with impurity such as phosphorus (P) implanted therein. A capacitor film 105 formed of an Si₃N₄ film, a Ta₂O₅ film, or the like, and an upper electrode 107 formed of a polysilicon film similar to that of the lower electrode 104 are laminated in this order along the inner wall of the cylinder 103. By increasing the depth of the cylinder 103, the surface area of the lower electrode 104 and of the upper electrode 107 is increased.

It is to be noted that, when a polysilicon film is used as the lower electrode 104 of the capacitor element, a method has been attempted in which a minute unevenness is provided on the surface of the lower electrode 104 to increase the surface area. More specifically, spherical or hemispherical grains called HSG (Hemispherical Grained Polysilicon) (not shown) are formed on the surface of the lower electrode 104. In a case that a Ta₂O₅ film is used as the capacitor film 105, a titanium nitride (TiN) film 106 for suppressing the reaction between the Ta₂O₅ film and polysilicon is formed on the Ta₂O₅ film.

On the other hand, as shown in FIG. 2, in the capacitor element of the stack structure, a convex-shaped lower electrode 204 formed of a polysilicon film with impurity such as phosphorus (P) implanted therein is formed on an interlayer insulating film 202 formed on the whole surface of a substrate. A capacitor film 205 formed of an Si₃N₄ film, a Ta₂O₅ film, or the like, and an upper electrode 207 formed of a polysilicon film similar to that of the lower electrode 204 are structured to be laminated in this order on the lower electrode 204. By forming the convex-shaped lower electrode 204 so as to be large, the surface area of the lower electrode 204 and of the upper electrode 207 are made large. It is to be noted that, in a case a polysilicon film is used as the lower electrode 204 of the capacitor element, as shown in FIG. 2, HSG 206 is formed to increase the surface area of the lower electrode 204.

Next, a method of manufacturing a semiconductor device (general-purpose DRAM) having the above capacitor element is described using FIGS. 3-5.

FIGS. 3A to 3G are sectional side elevations showing a manufacturing procedure of a semiconductor device having the capacitor element of the conventional cylinder structure. FIG. 4 is a sectional side elevation showing another manufacturing procedure of a semiconductor device having the capacitor element of the conventional cylinder structure. FIG. 9 is a sectional side elevation showing a manufacturing procedure of a semiconductor device having the capacitor element of the conventional stack structure.

It is to be noted that FIGS. 3-5 illustrate a case where, as transistors for memory cells, n-channel transistors having the MOS structure are formed on a p-type semiconductor substrate. It is also to be noted that, though transistors for the peripheral circuits are not shown in FIGS. 3-5, the structure of n-channel transistors for the peripheral circuits is the same as that of the transistors for the memory cells, and the structure of p-channel transistors is basically the same except that the kind of impurity in a channel region and in a source/drain region is different.

First, examples of the method of manufacturing the general-purpose DRAM having the capacitor element of the cylinder structure are described using FIGS. 3-4.

First, as element separating regions 111 for separating the respective transistors, grooves (STI: Shallow Trench Isolation) having uniform depth and filled with an oxide film are formed on a p-type semiconductor substrate 110 using a conventional method, as illustrated in FIG. 3A.

Then, after boron (B), for example, is implanted in a region for forming a transistor to form a channel region (not shown), a gate oxide film 112 at the thickness of about 70-80 angstroms is formed by thermally oxidizing the surface of the p-type semiconductor substrate 110. Further, a polysilicon film at the thickness of about 1,500 angstroms (3,000 angstroms or less) to be a gate electrode is formed on the gate oxide film 112 by CVD. By patterning them in a desired shape using photolithography, a gate electrode 113 is formed.

Then, arsenic (As) or phosphorus is implanted in the p-type semiconductor substrate 110 with the gate electrode 113 being used as the mask to form a source/drain (SD) extension region (not shown). Next, an insulating film which is a silicon oxide film, silicon nitride film, or laminations thereof is deposited over the whole surface and an etch-back process is carried out to form side walls 114 on side surfaces of the gate electrode 113. Then, with the gate electrode 113 and the side walls 114 being used as the mask, arsenic or phosphorus is implanted in the p-type semiconductor substrate 110 to form a source/drain region 115, as illustrated in FIG. 3B.

Then, an interlayer insulating film 116 formed of SiO₂ at the thickness of 5,000-8,000 angstroms is formed over the whole surface using atmospheric pressure CVD. A photoresist 117 is formed on the interlayer insulating film 116, patterning is carried out, and the interlayer insulating film 116 in an opening of the photoresist 117 is etched and removed, and a capacitor contact 118 is formed which connects a drain of the transistor to the upper surface of the interlayer insulating film 116 (FIG. 3C). It is to be noted that the interlayer insulating film 116 may be structured to include BPSG (Borophosphosilicate Glass).

Then, after the photoresist 117 is removed, a capacitor electrode 119 formed of a polysilicon film with phosphorus, for example, doped therein is buried in the capacitor contact 118. Further, a cylinder interlayer film 120 formed of BPSG or the like at the thickness of 6,000-14,000 angstroms is formed on the interlayer insulating film 116, and heat treatment is carried out at about 800° C.-850° C. for about 10-30 minutes to bake the BPSG. It is to be noted that the cylinder interlayer film 120 may be structured such that an SiO₂ film formed by atmospheric pressure CVD is laminated on the BPSG film.

Next, a photoresist 121 is formed on the whole surface, patterning is carried out, the cylinder interlayer film 120 in an opening of the photoresist 121 is etched and removed, and a groove (cylinder 122) which connects the capacitor contact 118 and the upper surface of the cylinder interlayer film 120 is formed (FIG. 3D). A capacitor element for the DRAM is formed in the cylinder 122.

Then, after the photoresist 121 is removed, a polysilicon film is formed all over the surface including the inner walls of the cylinder 122, as illustrated in FIG. 3E, thereby forming a lower electrode 123 of the capacitor element. The polysilicon film is doped with phosphorus (dose: about 1×10¹⁹-1×10²⁰ atoms/cm³) and has a thickness of about 1,500-3,000 angstroms. Further, a photoresist 124 is formed over the whole surface, and patterning is carried out such that the photoresist 124 is left only in the cylinder 122, wherein the polysilicon film on the upper surface of the cylinder interlayer film 120 is etched and removed.

Next, after the photoresist 124 in the cylinder 122 is removed, annealing (at about 500-600° C. for about 10-60 minutes) is carried out with silane deposited thereon to form nuclei of HSG on the lower electrode. One example, without limitation, of how the silane can be deposited to form nuclei of HSG is by irradiating the surface of the lower electrode with silane. One example, without limitation, of how this irradiation of the surface is carried out is molecular beam deposition. Further, by annealing in a vacuum (at 500-600° C. for 10 -60 minutes), grains are made to grow around the nuclei to form HSG 125, as illustrated in FIG. 3F.

Finally, a capacitor film 126, a TiN film 127, and an upper electrode 128 are formed in this order on the lower electrode 123, as illustrated in FIG. 3G. The upper electrode 128 is formed of polysilicon with phosphorus doped therein. Wiring follows using a conventional process.

It is to be noted that, although FIG. 3G omits the HSG 125 on the lower electrode 123 for the sake of simplicity of the drawing, actually, as shown in FIG. 3F, the HSG 125 remains on the lower electrode 123 formed on the inner walls of cylinder 122.

Further, in the above process, the HSG 125 is made to grow in the cylinder 122 after the polysilicon film on the cylinder interlayer film 120 is removed by an etch-back process. As shown in FIG. 4, after the HSG 125 is formed on the polysilicon film on the cylinder interlayer film 120 and in the cylinder 122, the polysilicon film and the HSG 125 on the upper surface of the cylinder interlayer film 120 are removed by an etch-back process, to leave the polysilicon film (lower electrode 123) and the HSG 125 in the cylinder 122. Such a procedure is disclosed in, for example, Japanese Patent Application Laid-open No. Hei 11-284139.

Next, an example of the method of manufacturing the general-purpose DRAM having the capacitor element of the stack structure is described using FIGS. 5A-5D.

First, as shown in FIGS. 5A-5C, similar to the manufacturing process of the general-purpose DRAM having the capacitor element of the cylinder structure, an element separating regions 211 and a transistor are formed on a p-type semiconductor substrate 210. After an interlayer insulating film 216 is formed over the whole surface, a capacitor contact 218 is formed. It is to be noted that the interlayer insulating film 216 is structured to be a BPSG film with an SiO₂ film laminated thereto. The SiO₂ film is formed using atmospheric pressure CVD.

Then, a capacitor electrode 219 formed of a phosphorus-doped polysilicon film is buried in the capacitor contact 218, as illustrated in FIG. 5A. A phosphorus-doped polysilicon film (dose: about 1×10¹⁹-1×10²⁰ atoms/cm³), at the thickness of about 6,000-10,000 angstroms, is formed all over the surface. Then, as illustrated in FIG. 5B, a photoresist 224 is formed over the whole surface, and patterning is carried out, such that the photoresist 224 is left only in a region to be a lower electrode 223 of the capacitor element, and the unnecessary polysilicon film 222 on the interlayer insulating film 216 is etched and removed to form the lower electrode 223.

Next, after the photoresist 224 is removed, annealing (at about 500-600° C. for about 10-60 minutes) is carried out with silane (SiH₄) deposited thereon to form nuclei of HSG on the lower electrode 223. Further, by annealing in a vacuum (at 500-600° C. for 10-60 minutes), grains are made to grow around the nuclei to form HSG 225, as illustrated in FIG. 5C.

Finally, a capacitor film 227 and an upper electrode 228 formed of polysilicon with phosphorus doped therein are formed in this order on the lower electrode 223 (FIG. 5D). Wiring follows using a conventional process.

These days, a semiconductor device comprises not only a single function of a CPU, a logic circuit, a memory device, or the like, but also has multiple functions on one chip comprising a desired system. Such a system is called a system-on-chip (SOC).

In such a semiconductor device having a CMOS logic circuit portion such as a CPU and a logic circuit and a DRAM portion mixedly mounted thereon, when transistors for the CMOS logic circuit portion and transistors for memory cells of the DRAM portion are formed and then capacitor elements of the cylinder structure are formed according to the procedure shown in FIGS. 3C-3G, a failure may arise during the manufacturing process, in that the HSG does not form as desired in the growth process of the HSG shown in FIG. 3F.

On the other hand, in a semiconductor device having a CMOS logic circuit portion and a DRAM portion provided with a capacitor element of the stack structure mixedly mounted thereon, when the capacitor element of the stack structure is formed according to the procedure shown in FIG. 5A-5D, a failure may arise during the manufacturing process, in that the HSG does not form as desired in the growth process of the HSG shown in FIG. 5C.

More specifically, in a structure where a CMOS logic circuit portion and a DRAM portion provided with a capacitor element of the cylinder structure are mixedly mounted, the HSG does not form normally when a polysilicon film is formed on a cylinder interlayer film and in a cylinder, the polysilicon film on the cylinder interlayer film is removed by etching back, and then the HSG is formed in the cylinder. This is a problem which arises even when the conditions of formation of the HSG (nucleation time period of the HSG, annealing time period, and the like) are changed, and has repeatability.

It is to be noted that, in a capacitor element of the stack structure, the lower electrodes formed in the process shown in FIG. 5C are liable to collapse, and, if the distance between the lower electrodes is small, a manufacturing failure arises in that the HSGs are connected to each other. In particular, when both miniaturization and higher capacitance are required, it is necessary that thin and tall lower electrodes are formed closely together. Thus, the above manufacturing failures are more liable to arise. Therefore, in a semiconductor device of the next generation which is required to have a higher level of integration, it is preferable that the cylinder structure rather than the stack structure is used as the capacitor elements.

### SUMMARY OF THE INVENTION

One purpose of the present invention is to solve the above problem of the prior art. One object of the present invention is to provide a method of manufacturing a semiconductor device where HSG can be formed without fail on lower electrodes in cylinders for capacitor elements, even when the semiconductor device has a CMOS logic circuit portion and a DRAM portion provided with a capacitor element of the cylinder structure mixedly mounted on one chip.

An embodiment of the present invention relates to a method of manufacturing a system-on-chip semiconductor device having a CMOS logic circuit portion and a DRAM portion mixedly mounted on one chip. Preferably, the DRAM portion has a cylinder-type capacitor lower electrode formed of polysilicon.

The method comprises a first step of forming transistors of the CMOS logic circuit portion and of the DRAM portion, respectively, a second step of forming an interlayer film over the whole surface and forming a groove portion in the interlayer film, a third step of forming a polysilicon film over the whole surface and forming HSG on the surface of the polysilicon film, and a fourth step of removing the polysilicon film, except in the groove portion, and forming the capacitor lower electrode.

In the manufacturing method, the polysilicon film is formed on the cylinder interlayer film and on the inner wall of the cylinder. The HSG is formed on the polysilicon film. The polysilicon film and the HSG on the cylinder interlayer film are removed while the polysilicon film and the HSG on the inner wall of the cylinder is kept. Accordingly, the HSG is reliably formed on the inner wall of the cylinder. Therefore, a miniaturized capacitor element having high capacitance is formed in a semiconductor device with a CMOS logic circuit portion and a DRAM portion mixedly mounted on one chip.

As an exemplary embodiment, the interlayer film comprises BPSG, and boron is implanted in a gate electrode formed of polysilicon of a p-channel transistor of the CMOS logic portion.

In the above manufacturing method, the HSG is formed on the polysilicon film, which is formed on the interlayer film and on the inner wall of the cylinder. Then the polysilicon film and the HSG on the upper surface of the interlayer film are removed, leaving the polysilicon film and the HSG on the inner wall of the cylinder. Therefore, the HSG is formed reliably on the inner wall of the cylinder even when the semiconductor device has a CMOS logic circuit portion and a DRAM portion mixedly mounted thereon.

### BRIEF DESCRIPTION OF THE DRAWINGS

The above and other objects, advantages and features of the present invention will be more apparent from the following description taken in conjunction with the accompanying drawings, in which:

FIG. 1 is a sectional side elevation showing the structure of a part of a general-purpose DRAM having capacitor elements of the cylinder structure;

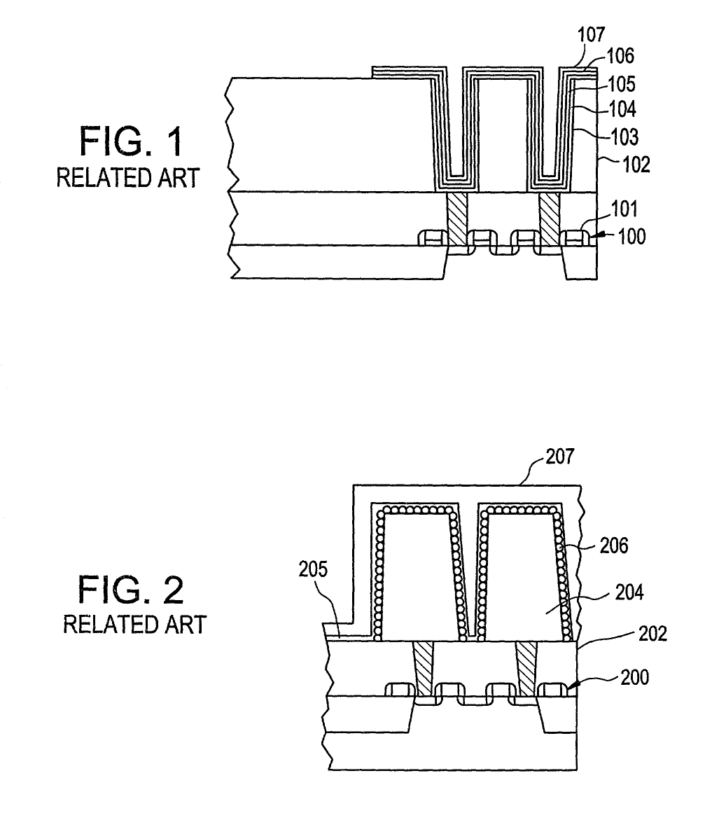

FIG. 2 is a sectional side elevation showing the structure of a part of a general-purpose DRAM having capacitor elements of the stack structure;

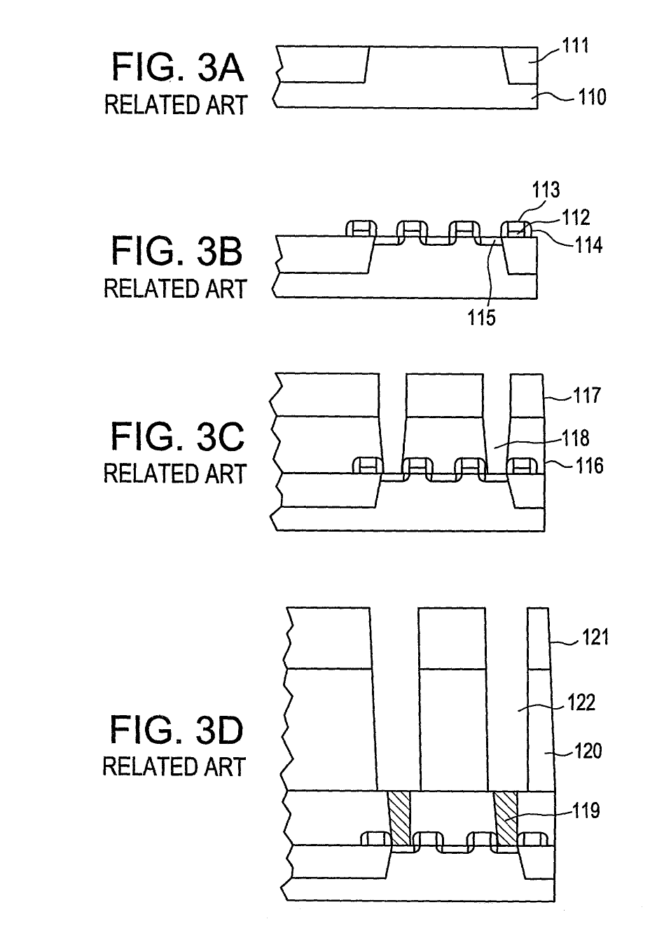

FIGS. 3A-3G are sectional side elevations showing a manufacturing procedure of a semiconductor device having a capacitor element of a conventional cylinder structure;

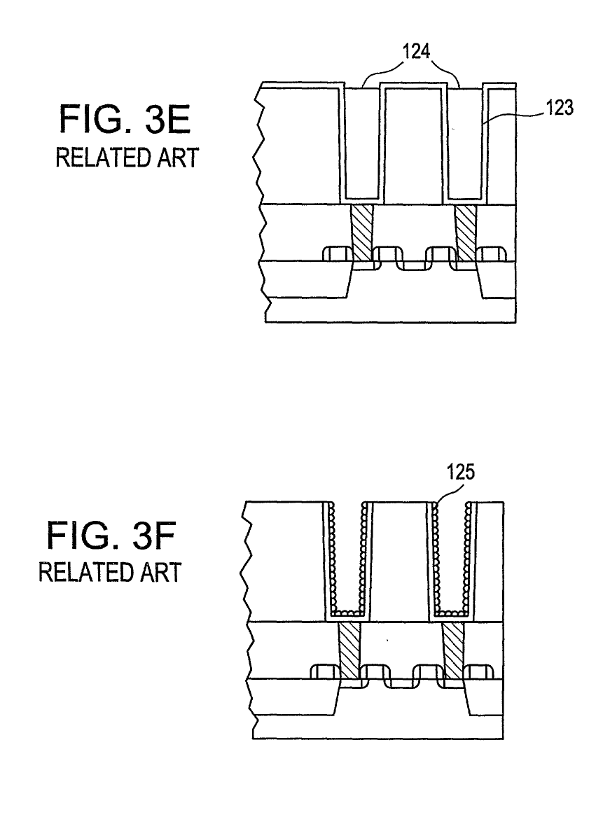

FIG. 4 is a sectional side elevation showing another manufacturing procedure of a semiconductor device having a capacitor element of a conventional cylinder structure;

FIGS. 5A-5D are sectional side elevations showing a manufacturing procedure of a semiconductor device having a capacitor element of a conventional stack structure;

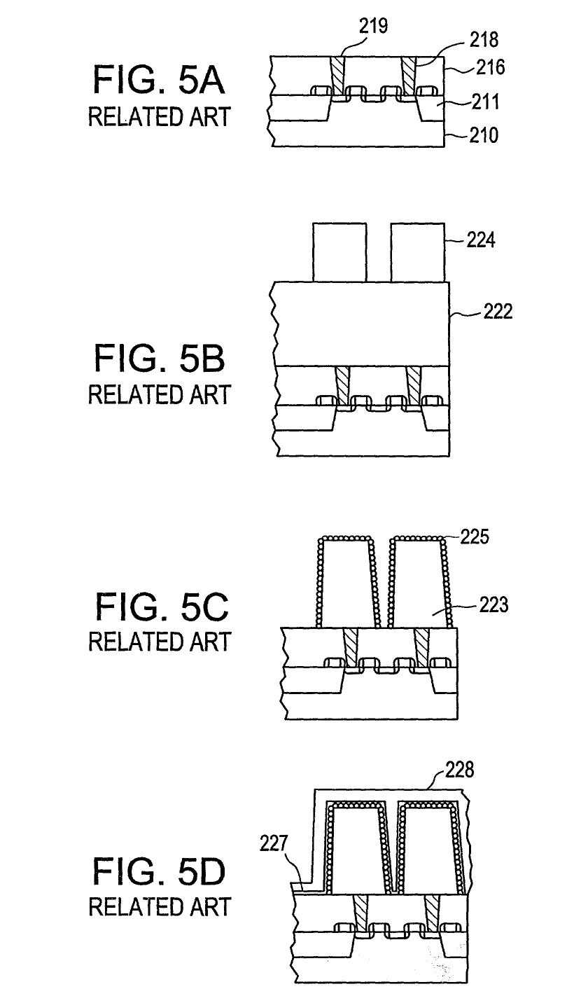

FIG. 6A is a plan view of a general-purpose DRAM in an example of arrangement of elements of a semiconductor device;

FIG. 6B is a plan view of a semiconductor device with a CMOS logic circuit portion and a DRAM mixedly mounted thereon in the example of arrangement of elements of a semiconductor device; and

FIGS. 7A-7G are sectional side elevations showing a manufacturing procedure of a semiconductor device according to the present invention.

### BRIEF DESCRIPTION OF THE PREFERRED EMBODIMENTS

The present invention is described with reference to the drawings. It is understood that the invention is not limited to this embodiment, which is provided as only one example of an implementation of the invention.

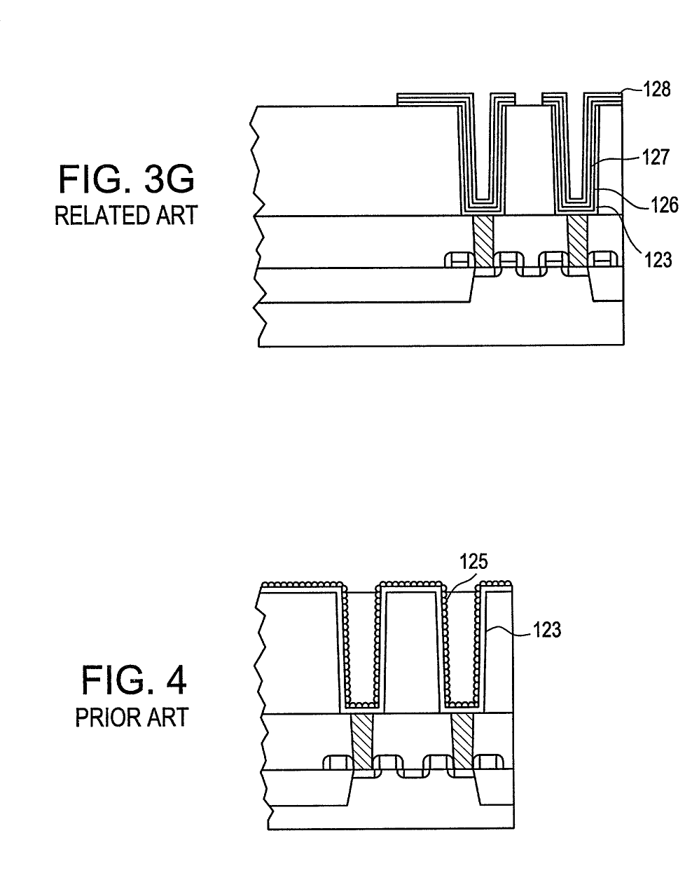

In a method of manufacturing a semiconductor device according to the present invention, a semiconductor device is formed having a CMOS logic circuit portion and a DRAM portion mixedly mounted thereon. The DRAM portion is provided with a capacitor element of the cylinder structure, similar to the manufacturing process of a general-purpose DRAM shown in FIG. 4. After HSG is formed on a cylinder interlayer film and on a polysilicon film in a cylinder, the polysilicon film and the HSG on the upper surface of the cylinder interlayer film are removed, respectively, and the polysilicon film and the HSG in the cylinder are left intact.

The inventor has found that, by manufacturing according to the above procedure, a capacitor element of a semiconductor device having a CMOS logic circuit portion and a DRAM portion provided with the capacitor element of the cylinder structure mixedly mounted thereon, the HSG is reliably formed in the cylinder.

The reason for this is not clear, but the cylinder interlayer film exposed by removing the polysilicon film before forming the HSG is thought to influence the abnormal growth of the HSG, in the procedure of forming the HSG in the cylinder after the polysilicon film on the upper surface of the cylinder interlayer film is removed.

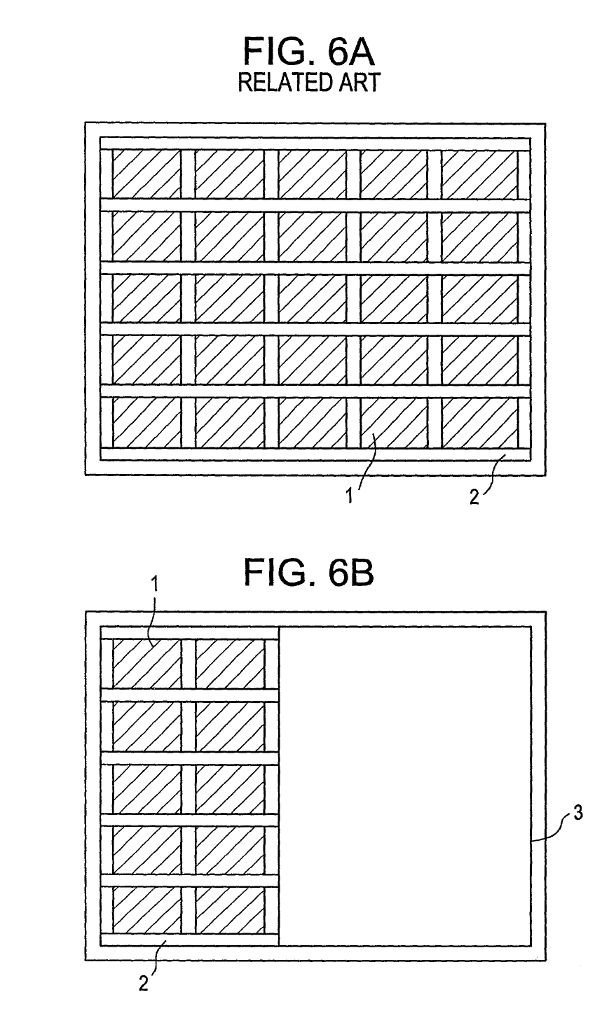

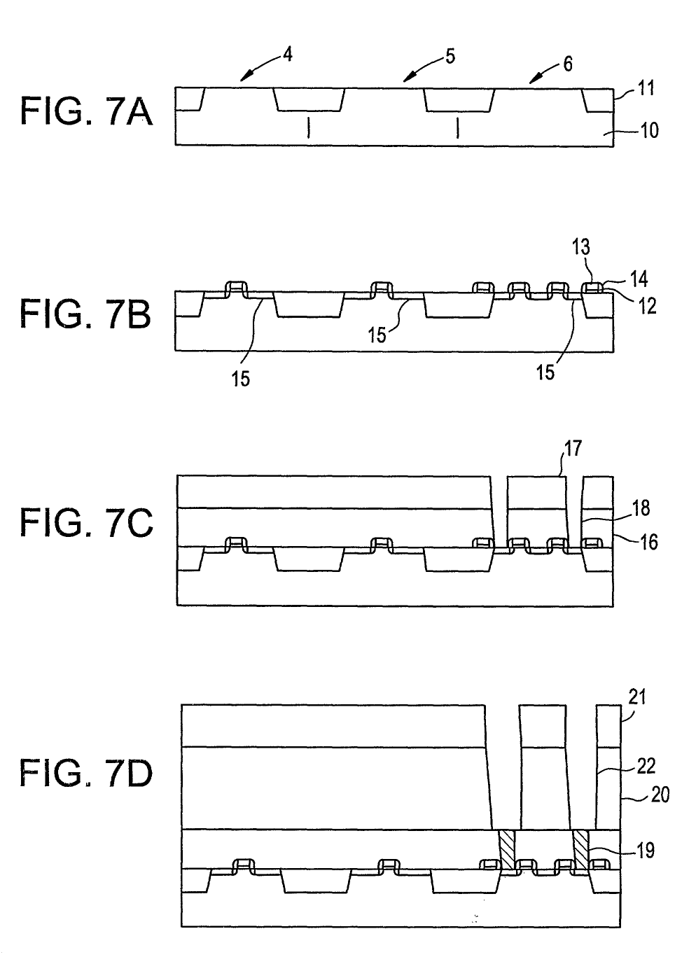

More specifically, in a general-purpose DRAM, for example, memory cells 1 and peripheral circuits 2 are disposed as shown in FIG. 6A. The ratio of the memory cells 1 to the area of the chip is 50 60%. On the other hand, in a semiconductor device with a CMOS logic circuit portion and a DRAM portion mixedly mounted thereon, since a CMOS logic circuit portion 3, memory cells 1 for the DRAM, and peripheral circuits 2 are disposed as shown, for example, in FIG. 6B, the ratio of the memory cells 1 to the area of the chip is 10-25%. Therefore, in a general-purpose DRAM, the ratio of a cylinder interlayer film exposed to the area of the chip is small when the HSG is formed. In comparison, in a semiconductor device with a CMOS logic circuit portion and a DRAM portion mixedly mounted thereon, the ratio of an exposed cylinder interlayer film to the area of the chip is large when the HSG is formed.

Further, regarding a general-purpose DRAM, BPSG in a cylinder interlayer film can be baked by carrying out heat treatment at about 800° C.-850° C. for about 10-30 minutes after a cylinder interlayer film is formed, in a semiconductor device with a CMOS logic circuit portion and a DRAM portion mixedly mounted thereon. However, since the characteristics of transistors for the CMOS logic circuit portion are changed by applying a high temperature (800° C. or above), the above heat treatment can not be carried out. Therefore, unnecessary substances (such as moisture) in the BPSG can not be sufficiently removed, which are thought to adversely affect the growth of HSG.

Similarly, it is to be noted that, when a capacitor element of the stack structure is formed, an interlayer insulating film is exposed when HSG is formed. However, it is thought that with a stack structure the HSG is more reliably formed, compared with the cylinder structure, since the interlayer insulating film is thinner compared with the cylinder interlayer film, and, in particular, the absolute amount of BPSG is smaller.

The reason why heat treatment at a high temperature can not be carried out with regard to a semiconductor device with a CMOS logic circuit portion and a DRAM portion mixedly mounted on one chip is as follows.

Since high performance such as operating at a high speed is required of a transistor for a CMOS logic circuit portion, boron (B) is implanted in a gate electrode (polysilicon) of a p-channel transistor while phosphorus (P) is implanted in a gate electrode (polysilicon) of an n-channel transistor, implanting the same the kind of impurity in the channels and in the gate electrodes of respective transistors. By this, a depletion area is formed immediately under a gate oxide film, preventing a decrease in ON-current and a decrease in the conformability of channel depth as the channel depth increases.

Typically, a capacitor element is formed after a transistor is formed. When a high temperature is applied in the process of forming the capacitor element, boron (B) in the gate electrode of the p-channel transistor of the CMOS logic circuit portion diffuses to reach the inside of the channel through the gate oxide film. By the piercing phenomenon of boron, the threshold voltage VT of the transistor changes.

On the other hand, since high performance is not required of a transistor for a peripheral circuit of a general-purpose DRAM, phosphorus (P) is also implanted in a gate electrode (polysilicon) of a p-channel transistor, reducing the number of the process steps. Therefore, in such a structure, the above piercing phenomenon of boron does not occur.

Even in a case when boron is implanted in a gate electrode, the above piercing phenomenon of boron is prevented, since a gate oxide film of a transistor for a peripheral circuit of a general-purpose DRAM is formed to be thicker than that of a transistor for a CMOS logic circuit portion.

It is to be noted that, in a DRAM portion mounted on an SOC semiconductor device, since an existing general-purpose DRAM is mounted as a functional block, generally, the structure of a transistor for a peripheral circuit of a DRAM portion need not be same as that of a transistor for a CMOS logic circuit portion.

As described in the above, even with regard to a semiconductor device with a CMOS logic circuit portion and a DRAM having capacitor elements of the cylinder structure mixedly mounted on one chip, the HSG can be reliably formed without fail within the cylinder. According to the present invention, HSG is formed on a polysilicon film on a cylinder interlayer film and on the inner wall of a cylinder. The polysilicon film and the HSG are then removed from the upper surface of the cylinder interlayer film, while leaving intact the polysilicon film and the HSG in the cylinder.

Therefore, a capacitor element which has high capacitance and is miniaturized can be formed in a semiconductor device with a CMOS logic circuit portion and a DRAM portion mixedly mounted on one chip.

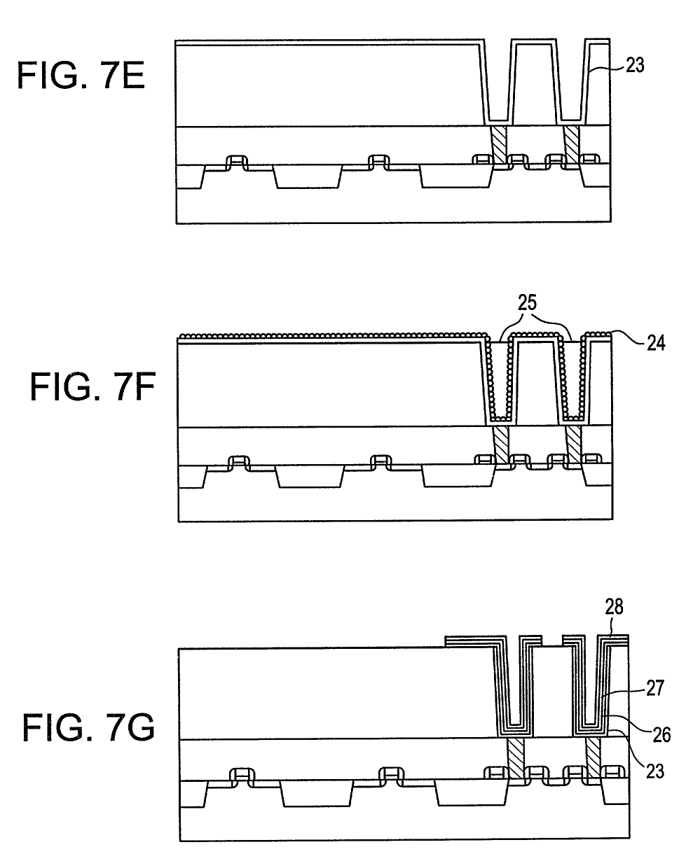

Next, an embodiment of a method of manufacturing a semiconductor device according to the present invention is described with reference to FIGS. 7A-7G. Other manufacturing methods are also described herein.

FIGS. 7A-7G are sectional side elevations showing a manufacturing procedure of a semiconductor device according to the present invention. In FIGS. 7A-7G, a logic portion having a CMOS logic circuit portion is formed, comprising MOS n-channel and p-channel transistors. A DRAM portion having memory cells is formed, comprising MOS n-channel transistors and capacitor elements of the cylinder structure. The above respective transistors are formed on the same semiconductor substrate. Though transistors for the peripheral circuits of the DRAM portion are not shown in FIGS. 7A 7G, the structure of n-channel transistors for the peripheral circuits is the same as that of the transistors for the memory cells, and the structure of p-channel transistors is basically the same, except that the kind of impurity in a channel region and in a source/drain region may be different.

In one embodiment of a method of manufacturing a semiconductor device according to the present invention, as element separating regions 11 for separating the respective transistors of the CMOS logic circuit portion and of the DRAM portion, grooves (STI) having uniform depth and filled with an oxide film are formed on a semiconductor substrate 10 using a conventional method, as illustrated in FIG. 7A.

Then, boron, for example, is implanted in a p-channel transistor forming region 5 to form an n-well region (not shown). Arsenic or phosphorus is implanted in an n-channel transistor forming region 4 (including a region 6 for forming a transistor for a memory cell) to form a p-well region (not shown). Further, boron is implanted in the n-channel transistor forming regions 4 and 6 to form channel regions (not shown), and arsenic or phosphorus is implanted in the p-channel transistor forming region to form a channel region (not shown).

Then, a gate oxide film 12 is formed to a thickness of about 30-40 angstroms, by thermally oxidizing the surface of the semiconductor substrate 10. A polysilicon film is formed on the gate oxide film 12 by CVD to a thickness of about 1,500 angstroms (3,000 angstroms or less) to be a gate electrode. By patterning the gate oxide film 12 and the polysilicon film in a desired shape using photolithography, gate electrodes 13 of the respective transistors are formed.

Then, arsenic or phosphorus is implanted in the n-channel transistor forming regions 4 and 6, with the gate electrode 13 being used as a mask to form an SD extension region (not shown). Similarly, boron is implanted in the p-channel transistor forming region 5 to form an SD extension region (not shown).

Next, an insulating film is deposited over the whole surface and an etch-back process is carried out to form respective side walls 14 on side surfaces of the respective gate electrodes. The insulating film may be, for example, a silicon oxide film, a silicon nitride film, or laminations thereof. Then, as illustrated in FIG. 7B, with the gate electrode 13 and the side walls 14 being used as a mask, arsenic or phosphorus is implanted in the n-channel transistor forming regions 4 and 6 to form source/drain regions 15. Boron is implanted in the p-channel transistor forming region 5 to form another source/drain region 15. Depending on the ion implantation process utilized, arsenic or phosphorus may be implanted in the gate electrodes (polysilicon) of the n-channel transistors and boron may be implanted in the gate electrode of the p-channel transistor.

Then, an interlayer insulating film 16 comprising SiO₂ is formed over the whole surface of the semiconductor substrate 10, to a thickness of 5,000-8,000 angstroms, using atmospheric pressure CVD. A photoresist layer 17 is formed on the interlayer insulating film 16 and patterned. The interlayer insulating film 16 below openings through the patterned photoresist 17 is etched and removed. A capacitor contact 18 is formed, connecting a drain of the transistor 6 for the memory cell to the upper surface of the interlayer insulating film 16, as illustrated in FIG. 7C. The interlayer insulating film 16 may include BPSG.

Then, after the photoresist 17 is removed, polysilicon doped with phosphorus, for example, is buried by CVD. Unnecessary polysilicon is removed by an etch-back process. The remaining polysilicon in the capacitor contact 18 forms a capacitor electrode 19.

Then, a cylinder interlayer film 20 comprising BPSG is formed over the whole surface to a thickness of about 6,000-14,000 angstroms. The cylinder interlayer film 20 may be structured such that an SiO₂ film formed by atmospheric pressure CVD is laminated on the BPSG film.

Next, a photoresist layer 21 is formed on the whole surface and patterned. The cylinder interlayer film 20 below openings in the photoresist 21 is etched and removed. As illustrated in FIG. 7D, a cylinder 22 is formed as a groove which connects the capacitor contact 18 and the upper surface of the cylinder interlayer film 20. A capacitor element for the DRAM will be formed within this cylinder 22.

Then, after the photoresist 21 is removed, a polysilicon film is formed to be a lower electrode 23 of the capacitor element. As illustrated in FIG. 7E, the polysilicon is formed all over the surface including the inner wall of the cylinder 22, to a thickness of about 1,500-3,000 angstroms, and is doped with phosphorus (dose: about 1×10¹⁹-1×10²⁰ atoms/cm³).

Next, annealing (at about 500-600° C. for about 10-60 minutes) is carried out with silane deposited thereon, forming nuclei of HSG on the lower electrode 23, on the cylinder interlayer film 20, and on the inner walls of the cylinder 22. Further, by annealing in a vacuum (at 500-600° C. for 10-60 minutes), grains are made to grow around the nuclei to form HSG 24 on the polysilicon film, on the cylinder interlayer film 20, and on the inner walls of the cylinder 22.

Then, as illustrated in FIG. 7F, a photoresist 25 is formed over the whole surface, and patterned such that the photoresist 25 is left only in the cylinder 22. The polysilicon film 23 and the HSG 24 on the upper surface of the cylinder interlayer film 20 is then etched and removed, using the patterned photoresist 25 as a mask.

Finally, the photoresist 25 in the cylinder 22 is removed. As illustrated in FIG. 7G, a capacitor film 26, and an upper electrode 28 made of polysilicon, are formed in this order on the lower electrode 23. Wiring follows using a conventional process.

If a Ta₂O₅ film is used as the capacitor film 26, a TiN film 27 for suppressing the reaction between the Ta₂O₅ film and polysilicon is formed on the Ta₂O₅ film, as illustrated in FIG. 7G. Further, while FIG. 7G omits the HSG 24 on the lower electrode 23 for the sake of simplicity of the drawing, in actuality, as shown in FIG. 7F, the HSG 24 remains on the lower electrode 23 formed on the inner walls of cylinder 22.

In the above described embodiment of the present invention, the polysilicon film is formed on an interlayer film and on the inner wall of a cylinder. The HSG is formed on the polysilicon film. The polysilicon film and the HSG on the upper surface of the interlayer film are removed while the polysilicon film and the HSG on the inner wall of the cylinder is kept intact. A benefit of this method is that the HSG is reliably formed on the inner wall of the cylinder without fail. Accordingly, a miniaturized capacitor element having high capacitance is reliably formed in a semiconductor device with a CMOS logic circuit portion and a DRAM portion mixedly mounted on one chip.

The present invention is not limited to the above embodiments, and it is contemplated that numerous modifications may be made without departing from the spirit and scope of the invention. The manufacturing method, as described above with reference to the drawings, is a merely an exemplary embodiment of the invention, and the scope of the invention is not limited to these particular embodiments. Accordingly, other structural configurations and other materials may be used, without departing from the spirit and scope of the invention as defined in the following claims.

What is claimed is:

1. A method of manufacturing a system-on-chip semiconductor device, including a CMOS logic circuit portion and a DRAM portion, comprising the steps of:
forming at least a first transistor on a substrate at said CMOS logic circuit portion;
forming at least a second transistor on said substrate at said DRAM portion; forming an interlayer film on said substrate at said CMOS logic circuit portion and on said substrate at said DRAM portion, covering said at least a first transistor and said at least a second transistor;
forming a groove in said interlayer film by removing a portion of said interlayer film at said DRAM portion;
forming a first polysilicon film on an upper surface of said interlayer film at said CMOS logic circuit portion and at said DRAM portion, and a second polysilicon film on an inner wall of said groove at said DRAM portion,
forming a first HSG on a surface of said first polysilicon film and a second HSG on a surface of said second polysilicon film; and
removing said first HSG and said first polysilicon film.

2. The method of manufacturing a system-on-chip semiconductor device as claimed in claim 1,
wherein said step of forming said at least a first transistor includes a step of forming a first gate insulating layer, and
wherein said step of forming said at least a second transistor includes a step of forming a second gate insulating layer,
wherein said first gate insulating layer is thinner that said second gate insulating layer.

3. The method of manufacturing a system-on-chip semiconductor device as claimed in claim 2,
wherein said at least a second transistor comprises a peripheral circuit transistor and a switching transistor, and
wherein said peripheral circuit transistor and said switching transistor have similar structures.

4. The method of manufacturing a system-on-chip semiconductor device as claimed in claim 3, wherein said step of forming an interlayer film comprises steps of:
forming a first interlayer film comprising a silicon oxide layer; and thereafter
forming a second interlayer film comprising a BPSG film.

5. The method of manufacturing a system-on-chip semiconductor device as claimed in claim 4, further comprising steps of:
forming an opening in said first interlayer film over a diffusion region of said switching transistor; and
forming a capacitor electrode in said opening in said first interlayer film,
wherein said capacitor electrode is connected to said diffusion region of said switching transistor.

6. The method of manufacturing a system-on-chip semiconductor device as claimed in claim 5, wherein said groove is formed in said second interlayer film, and said second polysilicon is connected to said capacitor electrode.

7. The method of manufacturing a system-on-chip semiconductor device as claimed in claim 6, further comprising steps of:
forming a first photoresist layer on said first HSG and a second resist layer on said second HSG; and
removing said first photoresist layer to expose said first HSG.

8. The method of manufacturing a system-on-chip semiconductor device as claimed in claim 7, further comprising steps of:
forming a capacitor film on said first HSG after said step of removing said first photoresist layer; and
forming a upper electrode on said capacitor film.

9. The method of manufacturing a system-on-chip semiconductor device as claimed in claim 8, wherein said capacitor film comprises a Ta₂O₅ film; and
further comprising a step of forming a TiN film on said Ta₂O₅ before said step of forming said upper electrode.

10. The method of manufacturing a system-on-chip semiconductor device as claimed in claim 2, wherein said step of forming said at least a first transistor further comprises steps of:
forming a first gate electrode comprising polysilicon; and
doping the polysilicon of the first gate electrode with boron,
wherein said at least a first transistor comprises a p-channel transistor having said first gate.

11. The method of manufacturing a system-on-chip semiconductor device as claimed in claim 10, wherein said step of forming at least a first transistor further comprises steps of:
forming a second gate electrode comprising polysilicon;
doping the polysilicon of the second gate electrode with phosphorous;
wherein said at least a first transistor comprises a n-channel transistor having said second gate.

12. The method of manufacturing a system-on-chip semiconductor device as claimed in claim 2, wherein said step of forming an interlayer film comprises a step of forming a BPSG film.

13. The method of manufacturing a system-on-chip semiconductor device as claimed in claim 12, wherein said step of forming an interlayer film further comprises a step of forming a silicon oxide layer prior to forming said BPSG film, wherein said BPSG film is formed on said silicon oxide film.

14. The method of manufacturing a system-on-chip semiconductor device as claimed in claim 2, wherein said DRAM portion comprises a memory cell portion and a peripheral circuit portion, and a surface area of said memory cell portion is 10 to 25% of a sum of surface areas of said DRAM portion and said CMOS logic circuit portion.

15. The method of manufacturing a system-on-chip semiconductor device as claimed in claim 14, wherein said surface area of said memory cell portion is 50 to 60% of the surface area of said DRAM portion.

16. A method of manufacturing a system-on-chip semiconductor device including a CMOS logic circuit portion and a DRAM portion, said DRAM portion comprising a cylinder type capacitor, the method comprising the steps of:
forming a first transistor on a substrate at said CMOS logic circuit portion;
forming a second transistor on said substrate at said DRAM portion;
forming an interlayer film on said substrate at said CMOS logic circuit portion and on said substrate at said DRAM portion, covering said first transistor and said second transistor;
forming a groove in said interlayer film by removing a portion of said interlayer film at said DRAM portion;
forming a polysilicon film on a said interlayer film at said CMOS logic circuit portion and at said DRAM portion, and on a inner wall of said groove at said DRAM portion,
forming a HSG on a surface of said polysilicon film; and
removing said HSG and said polysilicon film from an upper surface of said interlayer film, retaining at least a portion of said HSG in said groove and at least a portion said polysilicon in said groove.

17. The method of manufacturing a system-on-chip semiconductor device as claimed in claim 16,
wherein said step of forming said at least a first transistor includes a step of forming a first gate insulating layer, and
wherein said step of forming said at least a second transistor includes a step of forming a second gate insulating layer,
wherein said first gate insulating layer is thinner that said second gate insulating layer.

18. The method of manufacturing a system-on-chip semiconductor device as claimed in claim 17, wherein said step of forming said first transistor further comprises steps of:
forming a first gate electrode comprising polysilicon; and
doping the polysilicon of the first gate electrode with boron,
wherein said first transistor comprises a p-channel transistor having said first gate.

19. The method of manufacturing a system-on-chip semiconductor device as claimed in claim 17, wherein said step of forming an interlayer film comprises a step of forming a BPSG film.
